(19) United States
(12) Patent Application Publication
(10) Pub. No.: US 2025/0227889 A1
(43) Pub. Date: Jul. 10, 2025

(54) DEVICES, SYSTEMS AND METHODS RELATING TO UNDERFLOOR CUBIC SUPPORT SYSTEMS (UCFSS) FOR RAISED ACCESS FLOORS (RAF)

(71) Applicant: Global Integrated Flooring Solutions, Kentwood, MI (US)

(72) Inventors: Charles M. Brown, Greenwood Village, CO (US); Christopher H. Ervin, Castle Pines, CO (US); Husam Ghazal, Mississauga (CA); Prisciliano Benigno Nieto, Jr., Clarksville, MI (US)

(73) Assignee: Global Integrated Flooring Solutions, Kentwood, MI (US)

(21) Appl. No.: 18/785,181

(22) Filed: Jul. 26, 2024

Related U.S. Application Data
(60) Provisional application No. 63/617,506, filed on Jan. 4, 2024.
(60) Provisional application No. 63/617,524, filed on Jan. 4, 2024.

(51) Int. Cl. H05K 7/20; H05K 7/14

(52) U.S. Cl. CPC H05K 7/20745; H05K 7/1488; H05K 7/1497; H05K 7/1498; H05K 7/20736

(57) ABSTRACT

Devices, systems and methods, etc., that provide tailored, typically modular, raised access floor (RAF) support systems, referred to herein as underfloor cubic support systems (UFCSS). The UFCSS comprise UFCSS 3-D frames wherein (typically) the vertical corner posts of the UFCSS 3-D frame also serve as support pedestals for a complementary RAF panel. The corner posts can be vertical columns at the corners of the cubic structure (and therefore the corresponding RAF panel).

### CROSS-REFERENCE TO RELATED APPLICATIONS

The present application claims the benefit of copending U.S. Provisional Patent Application Ser. No. 63/617,506, filed Jan. 4, 2024, and claims the benefit of copending U.S. Provisional Patent Application Ser. No. 63/617,524, filed Jan. 4, 2024, both of which are presently pending, which applications are incorporated herein by reference in their entirety.

### BACKGROUND

Historically, cooling of data centers has been accomplished using raised floors to create a plenum for cool air to be distributed throughout the data center server room to the server racks. More recently, many data center designs forego the raised floor, instead handling all of the air in the room above the building floor slab. Both approaches require large cooling units that move large volumes of air around large spaces, which is inefficient and unable to adjust locally closer to the servers.

Thus, there has gone unmet a need for devices, systems, methods, etc., for improved, more efficient, and/or less expensive cooling of data centers and other high-heat locations.

The present devices, systems, and methods, etc., provide solutions to one or more of these needs, and/or one or more other advantages.

### SUMMARY

The present systems, devices, and methods, etc., are directed to a 3-dimensional frame configured to hold and support a complementary flooring panel, for example a cube-shaped frame (the structures are referred to herein for convenience as “cubic” and are 3D but need not be strictly cubic; other 3D shapes such as rectangular, triangular, spherical or hexagonal, can be used as desired). Generally, such systems, methods, etc., are directed to underfloor cubic support systems (UFCSS) a raised access floors (RAF) and have UFCSS 3-D frames holding and supporting complementary raised access floor panels (complementary RAF panel), such that the RAF are at least partially, and typically completely, comprised of UFCSS 3-D frame-complementary RAF panel units.

Typically, RAF panels are mounted in a many-to-one relationship between the panel and the underlying support pedestals, for example one pedestal holding the abutting corners of 4 different flooring panels, and do not have cubic supporting structures. Additionally, RAF vertical support structures can be connected mechanically to each other with cross beams and fasteners, which can be installed on-site when the RAF panels are installed. Here, cubic support structures are typically configured complementary with the supported panel for a one-to-one ratio of panel to frame (i.e., one RAF panel per cube, although other ratios can also be useful) and can arrive at the installation location already assembled.

The present systems, devices and methods, etc., provide underfloor cubic support systems (UFCSS) for a raised access floor (RAF) comprising a UFCSS 3-D frame for holding and supporting a complementary raised access floor panel (complementary RAF panel) to provide a UFCSS 3-D frame-complementary RAF panel unit, wherein:
the UFCSS 3-D frame is configured to hold and support the complementary RAF panel above a subfloor and the UFCSS 3-D frame comprises at least 3 vertical corner posts connected to each other by cross-support bars, with each vertical corner post comprising a foot at a lower end configured to contact the subfloor and a pedestal head at an upper end holding the complementary RAF panel, and
the complementary RAF panel comprises at least 3 sides and is complementary to the UFCSS 3-D frame such that a horizontal size of the UFCSS 3-D frame and a horizontal size of the complementary RAF panel have an integral ratio relationship.

The UFCSS 3-D frame can comprise at least one variable height adjustment element operably connected to the foot and the pedestal head to at least one of increase or decrease a distance between the foot and the pedestal head, and the UFCSS 3-D frame can comprise at least a first variable height adjustment element at the foot and a second variable height adjustment element at the pedestal head.

The UFCSS 3-D frame can be connected by attachment elements to the complementary RAF panel to provide the 3D frame-complementary RAF panel unit. The complementary RAF panel floats atop the UFCSS 3-D frame to provide the 3D frame-complementary RAF panel unit. The UFCSS 3-D frame can comprise stringers spanning between upper ends of the corner posts, and a location of the complementary RAF panel atop the UFCSS 3-D frame can be at least partially established by positioners on the stringers. The positioners can be partial loops extending upwardly from the stringer, and the stringers can span between pedestal heads at upper ends of the corner posts. A number of the corner posts of the UFCSS 3-D frame can be the same as a number of vertices of the complementary RAF panel and wherein each corner post can be attached to and supports a corresponding vertex of the complementary RAF panel. The UFCSS 3-D frame can have 4 corner posts and can be cuboid or a cube.

The complementary RAF panel can comprise 4 sides and the integral ratio relationship can be one complementary RAF panel to one UFCSS 3-D frame. The complementary RAF panel does not extend beyond any of the sides of the horizontal size of the UFCSS 3-D frame. The integral ratio relationship can be two complementary RAF panels to one UFCSS 3-D frame, four complementary RAF panels to one UFCSS 3-D frame, or one complementary RAF panel to two UFCSS 3-D frames. The UFCSS 3-D frame further can comprise an anti-rotation element that locks the pedestal head at a desired height and position, and in certain embodiments the pedestal head does not extend beyond the sides of the complementary RAF panel whereas in other embodiments the pedestal head extends beyond the sides of the complementary RAF panel, the pedestal head further comprising adjacent-pedestal head attachment elements for attaching to at least one adjacent corner post of at least one adjacent UFCSS 3-D frame. The adjacent-pedestal head attachment elements can be for attaching to an adjacent-pedestal head of the at least one adjacent corner post.

The UFCSS can comprise at least a first UFCSS 3-D frame-complementary RAF panel unit and a second UFCSS 3-D frame-complementary RAF panel unit and the system further can comprise at least one locator element disposed between each of the first UFCSS 3-D frame-complementary RAF panel unit and the second UFCSS 3-D frame-complementary RAF panel unit to hold the respective first UFCSS 3-D frame-complementary RAF panel unit and the second UFCSS 3-D frame-complementary RAF panel unit at a selected position relative to each other. The locator element can be connectable between a) a first corner post of the first UFCSS 3-D frame-complementary RAF panel unit and b) a second corner post of the second UFCSS 3-D frame-complementary RAF panel unit. The underfloor cubic support system can comprise at least a third UFCSS 3-D frame-complementary RAF panel unit and a fourth UFCSS 3-D frame-complementary RAF panel unit and wherein locator elements can be located between and positioning adjacent corners of all four of the UFCSS 3-D frame-complementary RAF panel units.

The locator element can be disposed between and connected to adjacent corner posts of all four of the UFCSS 3-D frame-complementary RAF panel units and can tilt between adjacent corner posts. The locator element can be a locator plate, and the locator plate can comprise adjustable bevels such that a lower surface of the locator plate can be tilted between and relative to adjacent UFCSS 3-D frame-complementary RAF panel units and an upper surface of the locator plate can be flat between and relative to adjacent UFCSS 3-D frame-complementary RAF panel units.

The cross-support bars of at least two different, adjacent UFCSS 3-D frames can be located at different heights within each of the two adjacent UFCSS 3-D frames, respectively. The cross-support bars of at least two UFCSS 3-D frames can form an in-frame open area for carrying pipes or conduits The UFCSS 3-D frame or the complementary RAF panel unit can comprise a flange or lip extending beyond the sides of the complementary RAF panel. At least one of the UFCSS 3-D frame or the complementary RAF panel unit can comprise information thereon describing components contained within the UFCSS 3-D frame or under the complementary RAF panel unit, respectively. Such information can include words, maps, diagrams, or other useful information about the components maintained below a given RAF panel or group of RAF panels, and can be printed, etched, mapped, contained in a decal, or otherwise permanently or temporarily imposed on the RAF Panel unit.

In some aspects, the present systems, devices and methods, etc., provide underfloor cubic support system kits (UFCSS kits) comprising a) a UFCSS 3-D frame as discussed herein configured to hold and support a complementary raised access floor (RAF) panel as discussed herein, typically above a subfloor. The UFCSS kits can also comprise at least one of a) instructions for use of the UFCSS kit or b) packaging materials for the UFCSS kit. The UFCSS kits can comprise a plurality of UFCSS 3-D frames and a corresponding plurality of complementary RAF panels, for example: a) at least two UFCSS 3-D frames configured to hold and support a complementary raised access floor (RAF) panel above a subfloor wherein the UFCSS 3-D frames comprise at least 3 vertical corner posts connected to each other by cross-support bars, with each corner post comprising a foot at a lower end configured to contact the subfloor and a pedestal head at an upper end for holding the complementary RAF panel, b) at least two complementary RAF panels sized and configured to complementarily attach specifically to the UFCSS 3-D frames such that complementary edges of the UFCSS 3-D frame and the complementary RAF panels can be substantially co-equal.

The UFCSS kits wherein at the UFCSS 3-D frames can be stacked upon each other, and the UFCSS 3-D frames can be disposed above at least one stack of the complementary RAF panels. UFCSS kits further can comprise a plurality of grilles for at least one input port and at least one output port in the RAF. The UFCSS 3-D frames can be stacked on a pallet in a 4×4×4 arrangement. The UFCSS kits further can comprise at least one of a semi-tractor trailer or cargo container containing the UFCSS 3-D frame and complementary RAF panel.

In further aspects, the present systems, devices and methods, etc., provide raised access floors (RAF) comprising or made from the underfloor cubic support systems (UFCSS) herein. The RAF can comprise a plurality of the UFCSS 3-D frame-complementary RAF panel units as discussed herein. Adjacent UFCSS 3-D frame-complementary RAF panel units in the RAF can be complementary such that there is no significant spaces between adjacent UFCSS 3-D frame-complementary RAF panel units.

The RAF further can comprise at least one underfloor server rack cooling system (UFSRCS) complementary to the UFCSS 3-D frames-complementary RAF panel units, the UFSRCS located within UFCSS 3-D frames and operably connected to a space above the RAF via an input port and an output port in the RAF, and the RAF further can comprise at least one server rack on the RAF. The RAF can be located between the input port and the output port with a hot air back side of the server rack adjacent the input port and a cool air side of the server rack adjacent the cold air output port.

In other aspects, the present systems, devices and methods, etc., provide underfloor cubic support systems (UFCSS) for a raised access floor (RAF) comprising a UFCSS 3-D frame as discussed herein wherein the UFCSS 3-D frame further comprises an anti-rotation element that locks the pedestal head and foot at a desired height and position relative to each other and relative to an adjacent UFCSS 3-D frame having an anti-rotation element, wherein the anti-rotation element comprises a rotating cogged wheel having teeth that extend at least slightly beyond a perimeter of the UFCSS 3-D frame, the teeth to interlace with adjacent teeth of an adjacent cogged wheel located on an adjacent UFCSS 3-D frame to prevent rotation of the cogged wheel and adjacent cogged wheel when the teeth can be interlaced. The UFCSS can comprise at least a first variable height adjustment element at the foot and a second variable height adjustment element at the pedestal head. The teeth can be angled teeth and have enlarged distal ends, and a given cogged wheel can rotate about a long axis of a given corner post holding the given cogged wheel. The system can comprise a plurality of the UFCSS 3-D frames and the teeth and adjacent teeth can be interlaced and prevent rotation of the cogged wheel and adjacent cogged wheel.

The present systems, devices and methods, etc., also include rooms and buildings have heat-intensive or cooling-intensive requirements, especially where such requirements are localized and vary significantly across different areas within the room, wherein such rooms and buildings include the underfloor cubic support systems (UFCSS) as discussed herein. Such rooms can be server rooms and the buildings can be data centers.

Also included herein are methods of making, transporting or using the UFCSS systems, 3-D frames, RAF panels, RAF floors, rooms and buildings as discussed herein. For example, methods include comprising placing a complementary raised access floor panel (complementary RAF panel) atop a complementary UFCSS 3-D frame to form a UFCSS 3-D frame-complementary RAF panel unit. The methods can further comprise:
the UFCSS 3-D frame can be configured to hold and support the complementary RAF panel above a subfloor and the UFCSS 3-D frame can comprise at least 3 vertical corner posts connected to each other by cross-support bars, with each vertical corner post comprising a foot at a lower end configured to contact the subfloor and a pedestal head at an upper end holding the complementary RAF panel, and
the complementary RAF panel can comprise at least 3 sides and can be complementary to the UFCSS 3-D frame such that a horizontal size of the UFCSS 3-D frame and a horizontal size of the complementary RAF panel have an integral ratio relationship.

The methods can further comprise placing a plurality of the complementary raised access floor panels (complementary RAF panels) a plurality of the complementary UFCSS 3-D frames to form a raised access floor comprising a plurality the UFCSS 3-D frame-complementary RAF panel units. The plurality of UFCSS 3-D frame-complementary RAF panel units can be placed in an abutting array such that a side of a first UFCSS 3-D frame-complementary RAF panel unit abuts at least one adjacent UFCSS 3-D frame-complementary RAF panel unit. In some embodiments, the first UFCSS 3-D frame-complementary RAF panel unit abuts at least four adjacent UFCSS 3-D frame-complementary RAF panel units.

The methods can further comprise placing at least one server rack on the RAF. The methods can further comprise placing an underfloor server rack cooling system (UFSRCS) between a subfloor and the RAF. The methods can further comprise placing the at least one server rack on the RAF between an input port and an output port of the underfloor server rack cooling system (UFSRCS), and if desired placing a hot air back side of the server rack adjacent the input port and a cool air side of the server rack adjacent the cold air output port.

The methods can further comprise placing a plurality of UFCSS 3-D frames and a plurality of complementary raised access floor panels (complementary RAF panels) as discussed herein on a pallet to form a kit. The methods can further comprise placing the kit within at least one of a semi-tractor trailer or cargo container, delivering the kit from a first location to a second desired location, or removing the UFCSS 3-D frames and the plurality of complementary RAF panel from the kit.

These and other aspects, features and embodiments are set forth within this application, including the following Detailed Description and attached drawings. In addition, various references are set forth herein, including in the Cross-Reference To Related Applications, that discuss certain systems, apparatus, methods and other information; all such references are incorporated herein by reference in their entirety and for all their teachings and disclosures, regardless of where the references may appear in this application.

### BRIEF DESCRIPTION OF THE DRAWINGS

FIG. 1 depicts a side plan stylized view of an underfloor cubic support system (UFCSS) as discussed herein.

FIG. 2 depicts a top plan stylized view of adjustable foot or head that interfaces with the feet or head of neighboring pedestal in a way that prevents rotation of the foot or head.

FIG. 3 depicts a top plan stylized view of adjustable foot or head that interfaces with the feet or head of neighboring pedestal in a way that prevents rotation of the foot or head.

FIG. 4 depicts a perspective stylized view of an underfloor cubic support system (UFCSS) as discussed herein.

FIG. 5 depicts an exploded perspective stylized view of an underfloor cubic support system (UFCSS) as discussed herein.

FIGS. 6A-6C depict views of a locator plate for an underfloor cubic support system (UFCSS) as discussed herein.

FIGS. 7A-7C depict views of a cogged wheel anti-rotation device for an underfloor cubic support system (UFCSS) as discussed herein.

FIG. 8 depicts a perspective stylized view of a pedestal head plate with protruding post for an underfloor cubic support system (UFCSS) as discussed herein.

FIG. 9 depicts a perspective stylized view of an underfloor cubic support system (UFCSS) as discussed herein having a mid-panel support.

FIGS. 10A and 10B depict a perspective stylized view of a further embodiment of a UFCSS 3-D frame-complementary RAF panel unit as discussed herein.

FIG. 11A depicts a perspective view of a pedestal head plate with locator elements, stringers and an attached RAF panel as discussed herein.

FIG. 11B depicts a perspective stylized view of modular cube mechanical and electrical component examples of underfloor cubic support system (UFCSS) as discussed herein, including for use in a kit.

FIG. 12 depicts a perspective stylized view of modular cube mechanical and electrical component examples of underfloor cubic support system (UFCSS) as discussed herein, including for use in a kit.

FIG. 13 depicts a perspective stylized view of modular cube mechanical and electrical component examples of underfloor cubic support system (UFCSS) as discussed herein, including for use in a kit.

FIG. 14 depicts a perspective stylized view of modular cube mechanical and electrical components of underfloor cubic support system (UFCSS) for delivery including in a semi-tractor trailer or cargo container, as discussed herein.

FIG. 15 depicts an underfloor cubic support system (UFCSS) with an underfloor server rack cooling system (UFSRCS) as discussed herein.

FIG. 16 depicts an underfloor cubic support system (UFCSS) with an underfloor server rack cooling system (UFSRCS) as discussed herein.

### DETAILED DESCRIPTION

The present devices, systems and methods, etc., provide tailored, typically modular, RAF support systems, referred to herein as underfloor cubic support system (UFCSS). The underfloor cubic support system (UFCSS) comprise UFCSS 3-D frames wherein (typically) the vertical corner posts of the UFCSS 3-D frame also serve as support pedestals for the RAF panel. The corner posts can be vertical columns at the corners of the cubic structure (and therefore the corresponding RAF panel).

As a general discussion of the UFCSS herein, the corner posts can have guide plates at the top and bottom that in turn have a shaped cutout which is concentric to the guide post. Typically, a given corner post of the UFCSS cubic structure supports a corner (or other desired location) of a corresponding RAF panel so the corner post and corresponding, complementary UFCSS 3-D frame is located correctly in relation to the RAF panel which it supports. The UFCSS 3-D frame which supports the raised floor can comprise variable-height components or configurations, such as threaded elements that can be screwed in-or-out to vary the relative height of pedestal heads that interact with the overlying RAF panel(s). In some embodiments, the guide posts are taller than the frame of the cubic support structure. The variable-height RAF pedestal heads comprise a connecting end of the pedestal head that connects to the RAF panel. The corners, typically vertical posts, of the UFCSS 3-D frames also engage the building's floor slab or other subfloor through an adjustable foot allowing variable heights to be achieved, making it easier to ensure the upper surfaces of the UFCSS cubic structure is level and the raised floor is flat. The UFCSS systems, 3-D frames, units, etc., herein can be used in combination with traditional pedestal systems in a given room or building.

The adjustable foot is configured and structured to interface with the feet of neighboring pedestal feet in a way that prevents rotation of the feet. The pedestal head includes a mounting post for locating the panel correctly in the XY plane while also interfacing with pedestal heads from neighboring panels in a way that prevents rotation of the head. The cube frame provides additional functionality for mounting mechanical and electrical components, such as acting as a duct for air transfer, and for routing wiring and/or plumbing on multiple XY planes under the floor. In some embodiments, the cube frame omits the vertical guide posts so the pedestal head connects directly with the guide plate at the top of the vertical post of the UFCSS 3-D frame. The pedestal head and foot components are typically vertically adjustable, for example to account for floor variations or other purposes.

In addition, raised floor installations historically require significant installer expertise to locate and glue in place independent support posts in exactly the right positions to create a 2′ by 2′ grid across large spaces with panel corners meeting at all intersections. The present systems, devices, methods, etc., reduce this complexity of installation problem by integrating the support posts into the cube shaped frame of the support structure. In one example, contiguous cubes create a 2′x2′ grid corresponding to 2′x2′ floor panels without requiring any additional measuring or gluing of the frames or posts. This also ensures the panels' corners are located correctly.

In addition, data centers and other buildings have great lengths of many wires and pipes snaking throughout the server room and other rooms, both in the ceiling and under the raised floor. Often, the space under the floor becomes very chaotic as these items compete for space. Wire racks requiring a separate installation procedure exist to address this issue by creating passageways under the raised floor. The present systems, devices, and methods, etc., simplify the issue by creating multiple levels of passageways that are part of the support structure requiring no secondary installation operation, for example where the UFCSS 3-D frame contains multiple levels of support cross bars and if desired with multiple levels sheeting or other panels (typically rough panels since aesthetics may not be a consideration for such underfloor sheeting/panels.

In addition, because the wires and pipes under the raised floor are hidden by the floor, in traditional situations it is often difficult for maintenance workers to identify locations of items that need to be maintained or changed. Printing an image or other instructions on a given UFCSS RAF panel or UFCSS 3-D frame of what lies underneath/within can reduce the locating problem. This aspect applies to conventional flooring systems as well.

Still further, it is typically necessary with traditional access floor installations to make sure the pedestal head cannot spin on the XY axis which could cause the support plate to become off center and/or raise or lower, thus destabilizing the floor panel(s) it supports. It is also necessary for the pedestal head to have a locator mechanism, so the floor panel sits in the right place. Historically, these two functions have been achieved separately in various designs of pedestal heads and their receiving posts. The present systems, devices, and methods, etc., combine the locating and anti-spin functions into the pedestal head plate, which can have an integral locator mechanism (i.e., the locator and variable height mechanisms can be integral or operably connected), thereby simplifying the function, reducing expenses, etc., by not relying on two separate design elements. The pedestal is prevented, in some embodiments, from spinning on the XY axis because the pedestal head is shaped and positioned to interface with the heads of neighboring pedestals (see, e.g., FIG. 2 below).

In addition, traditional raised floor pedestal systems must provide strength vertically (supporting weight on the floor) and laterally (“overturning moment”). The overturning moment requirement is typically met by gluing the base of the pedestal to the floor as part of the installation process. This creates a problem of variability in the lateral strength created as it is contingent on the installer applying the correct amount of glue in the correct spot, then allowing it to cure adequately. The present systems, devices, and methods, etc., reduce or eliminate this overturning moment variability problem by transferring the lateral load to the large cubicle support structure instead of the small portion of glue between the base and the floor.

The multi-function cubic support structures herein, including systems comprising such structures, can in some embodiments be used for cooling buildings and rooms having large cooling requirements such as data centers by providing a cooling approach localized to specific servers, server racks, server pods, etc., to be installed and implemented very effectively because the systems herein create independent modules for the cooling components (e.g., fan, cooling coil, air purifier). Thus, in some aspects and embodiments, the present systems, devices, and methods, etc., provide data centers and the like having small cooling units paired one-to-one or one-to-few server racks (server pods, etc.) and are housed under the floor in close proximity to the racks. The amount of air to be moved is greatly reduced, and the control of localized air temperatures is enhanced, each leading to better energy usage efficiency through more effective cooling of the servers. Thus, the systems, etc., herein provide better cooling solutions that are easily implemented.

In addition, the systems herein, including cooling components such as underfloor server rack cooling systems (UFSRCS), can easily be packaged in kits for delivery to the data center. For example, one 4′4′×4+′ pallet can hold sufficient cubes for supporting and cooling two server racks (see, e.g., FIGS. 11-13). This kit delivery approach reduces installation complexity, cost, etc.

In some aspects, the present systems, devices and methods, etc., provide cubic support structures for raised access floors, as well as RAF panels and/or full RAF floors comprising such cubic support structures, buildings comprising such RAF, and selected rooms having such cubic support structures within a building such as rooms holding large computers or servers or other components that have large heating and/or cooling needs.

In some aspects, such systems, devices and methods, etc., include subfloor systems such as electrical systems or HVAC systems, including for example HVAC systems suited for large server racks and those having separated fans and coils, for example where the fan and coil are separated at least as far as the length or width of a server rack on the floor above the fan and coil.

Turning to the Figures, the Figures herein depict some exemplary embodiments of such cubic support structures, etc., herein and are not necessarily drawn to scale.

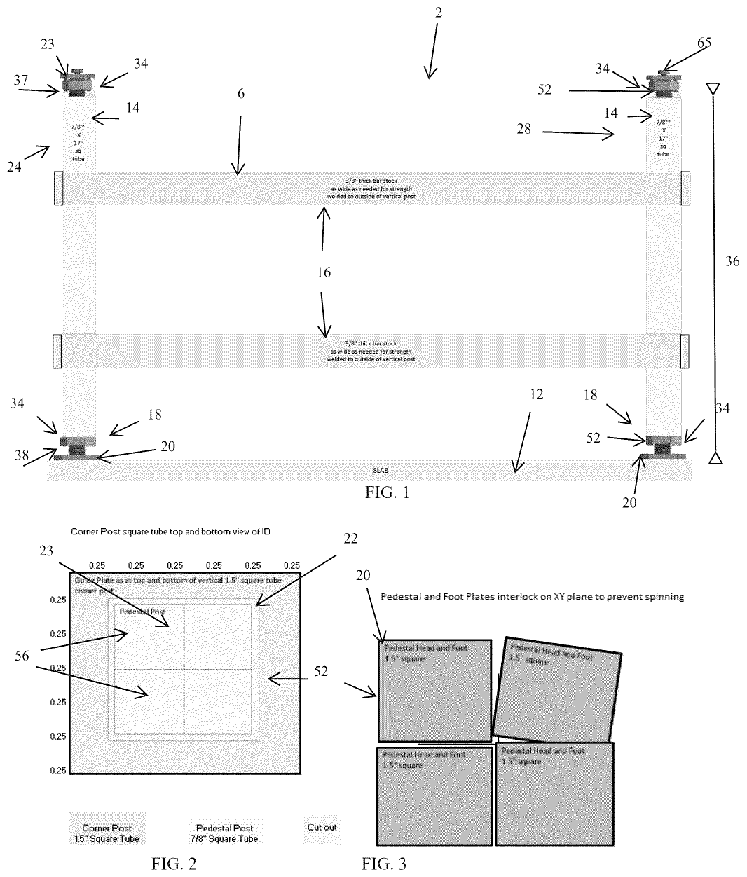

FIGS. 1-14 depict schematically underfloor cubic support systems (UFCSS) 2 for a raised access floor (RAF) 4 comprising a UFCSS 3-D frame 6 for holding and supporting a complementary raised access floor panel (complementary RAF panel 8) to provide a UFCSS 3-D frame-complementary RAF panel unit 10. In the embodiments shown in FIGS. 1-11, the UFCSS 3-D frame 6 is configured to hold and support the complementary RAF panel 8 above a subfloor 12 and the UFCSS 3-D frame 6 comprises at least 3 vertical corner posts 14 connected to each other by cross-support bars 16, with each vertical corner post 14 comprising a foot 18 at a lower end 20 configured to contact the subfloor and a pedestal head 22 at an upper end 24 holding the complementary RAF panel 8, and the complementary RAF panel 8 comprises at least 3 sides 26 and is complementary to the UFCSS 3-D frame 6 such that a horizontal size 30 of the UFCSS 3-D frame 6 and a horizontal sizes 32 the complementary RAF panel 8 have an integral ratio relationship. Integral ratio relationship indicates an integer to integer relationship such that one UFCSS 3-D frame can be provided for a desired integer number of RAF panels or vice versa, for example ratios of 1:1, 1:2, 2:1, 1:4 etc. UFCSS 3-D frames 6 and complementary RAF panels 8 can also be provided in partial sizes, for example from manufacture or on-site, such as providing half-size UFCSS 3-D frames 6 and complementary RAF panels 8 to close the gap between an edge of an array of UFCSS 3-D frame-complementary RAF panel units 10 and a wall.

The UFCSS 3-D frames 6 and complementary RAF panels 8 and if desired the completed UFCSS 3-D frame-complementary RAF panel units 10 can arrive at the installation location in modular presentation for easy assembly on-site or even already assembled. In some embodiments, as discussed further below, such as shown in FIGS. 11-13, the components can be packaged and delivered in underfloor cubic support system (UFCSS) kits 76.

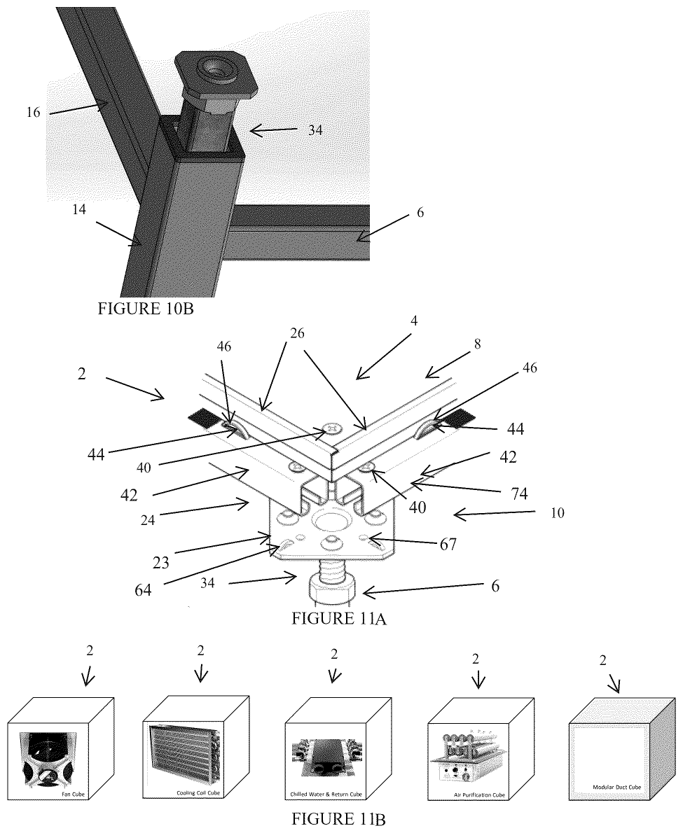

The UFCSS 3-D frame 6 typically comprises at least one variable height adjustment element 34 operably connected to the foot 18 and the pedestal head 22 to increase or decrease a distance 36 between the foot 18 and the pedestal head 22. In some embodiments, variable height adjustment elements 34 are operably connected to the both the foot 18 and the pedestal head 22. The complementary RAF panel 8 can float atop the UFCSS 3-D frame 6, as in FIG. 10A, or can be connected by attachment elements 40 such as screws, bolts, glue, etc., to provide the 3D frame-complementary RAF panel unit 10.

In the embodiment in FIG. 1, for the UFCSS 3-D frame 6, i.e., a multi-function support structure, the configuration of the pedestal head 22 and pedestal head plate 23 (the RAF support elements at the top of the UFCSS 3-D frame 6 that contact the RAF panels) is based on a one-to-one relationship between the cubic support structure and the corresponding RAF panel; although one-to-one is typical, other ratios can be used if desired or needed.

In certain embodiments, the horizontal length or size 32 of the complementary RAF panel 8 is the same length or shorter than the horizontal size 30 of the UFCSS 3-D frame 6. In some embodiments, the complementary RAF panel 8 does not extend beyond any of the sides 26 of the horizontal size 30 of the UFCSS 3-D frame 6.

Similarly, in some embodiments the complementary RAF panel 8 does not extend beyond the pedestal heads 22 or feet 20. FIGS. 2-3 depict exemplary pedestal heads 22 or feet 20 from adjacent UFCSS 3-D frames 6. These exemplary pedestal heads and feet feature an exemplary XY spin prevention system forming an anti-rotation element 52. The anti-rotation element 52 is an exemplary system of a height limiter that locks the pedestal head 22 or foot 20 at a desired height and position.

In certain embodiments, the number of the corner posts 14 of the UFCSS 3-D frame 6 is the same as a number of vertices 48 of the complementary RAF panel 8 and wherein each corner post 14 is attached to and supports a corresponding vertex 50 of the complementary RAF panel 8. As examples, the UFCSS 3-D frame 6 can have 4 corner posts 14 and is cuboid or a cube, and the complementary RAF panel 8 comprises 4 sides 26.

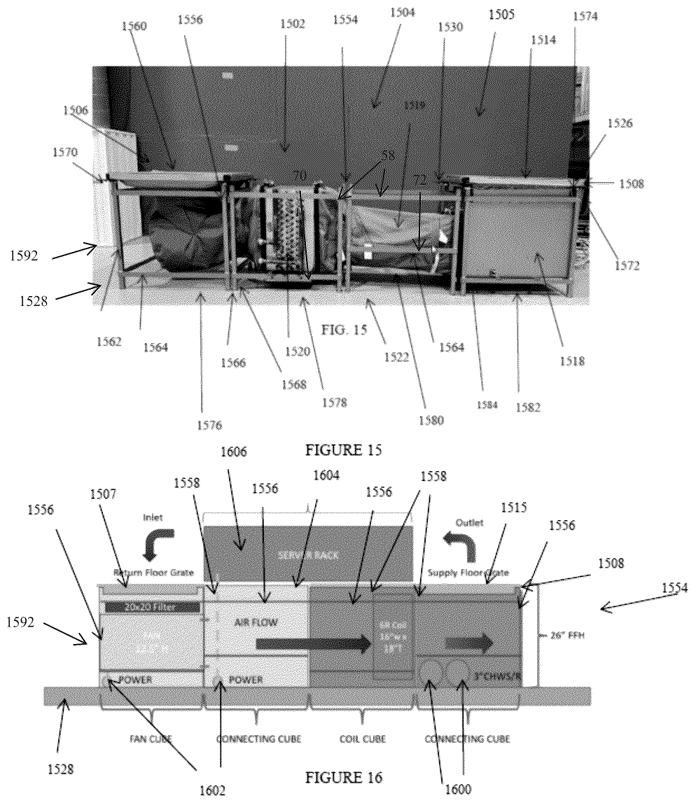

As shown for example in FIGS. 6A-6C, 8 and 9, the adjacent-pedestal head attachment element 54, pedestal head 22 can extend beyond the sides 26 of UFCSS 3-D frame 6 itself and the complementary RAF panel 8. The pedestal head 22 can further comprise adjacent-pedestal head attachment elements 54 for attaching to at least one adjacent corner post 56 or other connection structure of at least one adjacent UFCSS 3-D frame such as shown in FIGS. 15 and 16.

Adjacent-pedestal head attachment elements 54 are sized and configured for attaching to an adjacent-pedestal head of the at least one adjacent corner post, adjacent pedestal head or other adjacent-UFCSS 3-D frame or adjacent RAF panel.

In FIGS. 6A-6C, locator plate 66, which in this example is a pedestal head plate, has locator pins 59 that abut and hold adjacent UFCSS 3-D frame(s), and complementary RAF panels if desired, in a selected precise location relative to both the its supporting UFCSS 3-D frame(s) and adjacent complementary RAF panels. In FIG. 8, locator plate 66 is again a pedestal head plate 23 having a protruding post 65 that functions as a locator element.

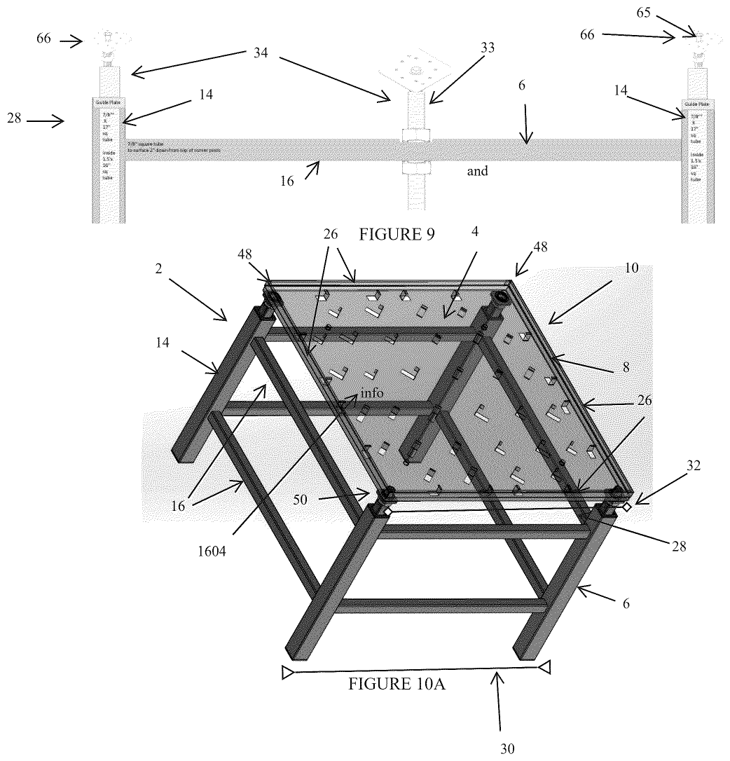

The cubic support structures, i.e., the UFCSS 3-D frames 6 herein, include a pedestal head mounting system with a protruding element or post 65 that uniquely locates the RAF panel 8 in a desired, correct XY plane position relative to the UFCSS 3-D frame and adjacent RAF panels. This can be accomplished, for example as shown in FIGS. 6A-6C, 7A-7C, 8 and 9, with a foot or pedestal head shape that interlocks with neighboring pedestal heads to prevent rotation of the pedestal head. The locator element can tilt between adjacent corner posts or feet as with the corner post locator element plates 66 in FIGS. 8 and 9. The locator element plates 66 locate and position adjacent UFCSS 3-D frames in desired, selected positions relative to each other, and if desired can also position adjacent RAF panels, and even UFCSS 3-D frame-complementary RAF panel units, relative to each. The locator element plates 66 can also comprise adjustable bevels such that a lower surface of the locator plate is tilted between and relative to, e.g., adjacent UFCSS 3-D frame-complementary RAF panel units. In such embodiments, the upper surface of the locator plate can be kept flat between adjacent UFCSS 3-D frame-complementary RAF panel units by adjusting the bevel of the plate, for example by shaving down the top surface of the plate to make it level relative to the surrounding units.

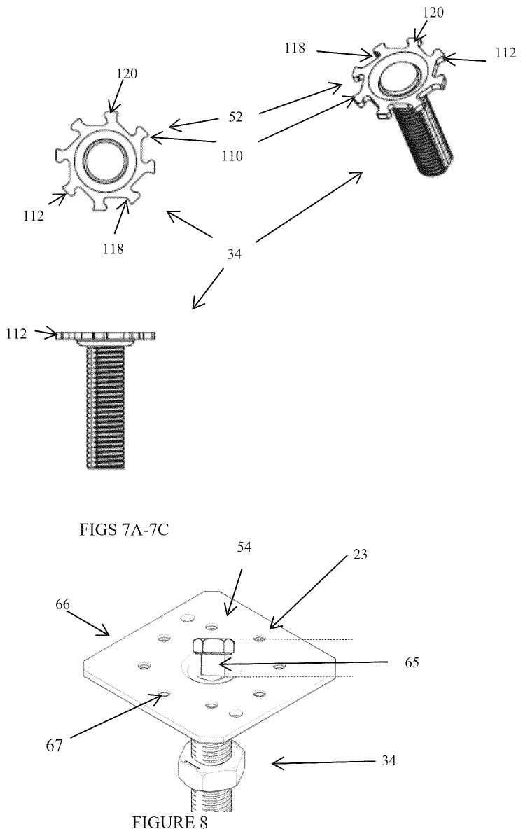

FIGS. 7A-7C depict views of a cogged wheel 110 anti-rotation device for a UFCSS as discussed herein. Briefly, in the embodiment shown, the UFCSS 3-D frame 6 comprises an anti-rotation element 52 that locks the pedestal head 22 and foot 18 at a desired height and position relative to each other and relative to an adjacent UFCSS 3-D frames, particularly when such complementary UFCSS frames or units have complementary anti-rotation elements. In this embodiment, the anti-rotation element 52 comprises a rotating cogged wheel 110 having teeth 112 that extend at least slightly beyond a perimeter of the UFCSS 3-D frame 6. The teeth 112 interlace with adjacent teeth of an adjacent cogged wheel located on an adjacent UFCSS 3-D frame to prevent rotation of the cogged wheel and adjacent cogged wheel when the teeth are interlaced.

The teeth 112 can be angled teeth 118 and have enlarged distal ends 120. A given cogged wheel 110 can rotate about a long axis of a given corner post 14 holding the given cogged wheel 110. The systems can comprises a plurality of adjacent UFCSS 3-D frames and the teeth 112 and adjacent teeth can be interlaced to prevent rotation of the cogged wheel and adjacent cogged wheel.

FIG. 9 depicts an embodiment wherein the UFCSS 3-D frame 6 has a mid-panel support structure 33. In some embodiments, this mid-panel support structure 33 can augment or replace the need for a corner-to-corner stringer to support heavy loads.

The complementary RAF panels 8 supported by the cubic support structures, or the UFCSS 3-D frame 6 or the complementary RAF panel unit 10, can have information 1604 such as printing, etching or other printed imagery or words including digital printing. Such information can include words, maps, diagrams, or other useful information about the components maintained below a given RAF panel or RAF panel unit, or group of RAF panels or RAF panel units, and can be printed, etched, mapped, contained in a decal, or otherwise permanently or temporarily imposed on the RAF panel unit. Such information 1604 can convey key components, wires, or pipes underneath the given raised floor panel and/or as a schematic for several RAF panels or even the room as a whole. Thus, such information can describe components contained within the UFCSS 3-D frame 6 or under the RAF floor including under a given complementary RAF panel unit 10. This can create a visual map of the floor easily seen and understood from above the floor. Thus, printing an image or other instructions on a given UFCSS RAF panel or UFCSS 3-D frame of what lies underneath/within can help a variety of issues including reducing the problem of future workers locating the components under the RAF. This aspect applies to conventional flooring systems as well, including for example printing or otherwise installing such information on the top RAF surfaces mounted on traditional pedestal systems. This printing approach can be useful where the UFCSS 3-D frames herein are used in combination with traditional pedestal systems in a given room.

Turning to some further discussion of the embodiments in FIGS. 10A and 10B, FIG. 10A shows a CAD rendering of the systems, methods, devices, etc., herein wherein:
a panel sits on top of the pedestal heads
guide plates which may be included or excluded in the design sit between the UFCSS 3-D frame and complementary RAF panel
the pedestal heads are inserted into cubic structure support posts
an insert in the panel receives the pedestal head protruding member
support bars integral to the structure create pathways for wiring and piping

FIG. 10B provides more detail of the pedestal head, wherein the pedestal head has a protruding element shown as a circular (disc) shape. Typically, the protracting element head has a shape configured to engage a corresponding element or corner in the RAF panel, such as a panel insert. For example, the protracting element head can be hexagonal, square, round with a detent, or otherwise configured to inhibit or eliminate unwanted spinning of the head.

FIG. 11A depicts a perspective view of a pedestal head plate 23 with locator element 64, stringers 42 and an attached RAF panel 8 forming a raised access floor (RAF) 4 as discussed herein The underfloor cubic support system (UFCSS) 2 further comprises attachment element holes 67 for attachment elements 40. In this embodiment, the UFCSS 3-D frame 6 comprises stringers 42 spanning between upper ends of the corner posts of adjacent RAF panels. The location of the complementary RAF panel 8 atop the UFCSS 3-D frame 6 is at least partially established by positioners 44 on the stringers 42. Here, the positioners 44 are partial loops 46 extending upwardly from the stringer, and the complementary RAF panel 8 nestles between the partial loops 46. In some embodiments, adjacent complementary RAF panels 8 abut the opposed sides of the partial loops 46 so that they are well-positioned relative to each other, including that such positioning places the components such that there are no significant spaces between adjacent complementary RAF panels 8, adjacent UFCSS 3-D frames 6, or adjacent UFCSS 3-D frame-complementary RAF panel units 10. Such spaces have no undesired openings through which items above the RAF could fall, and are typically less than 0.50″, 0.40″, 0.30″, 0.20″, 0.10″ as where needed or desired. In some embodiments the side of one complementary RAF panel abuts the corresponding side of an adjacent complementary RAF panel.

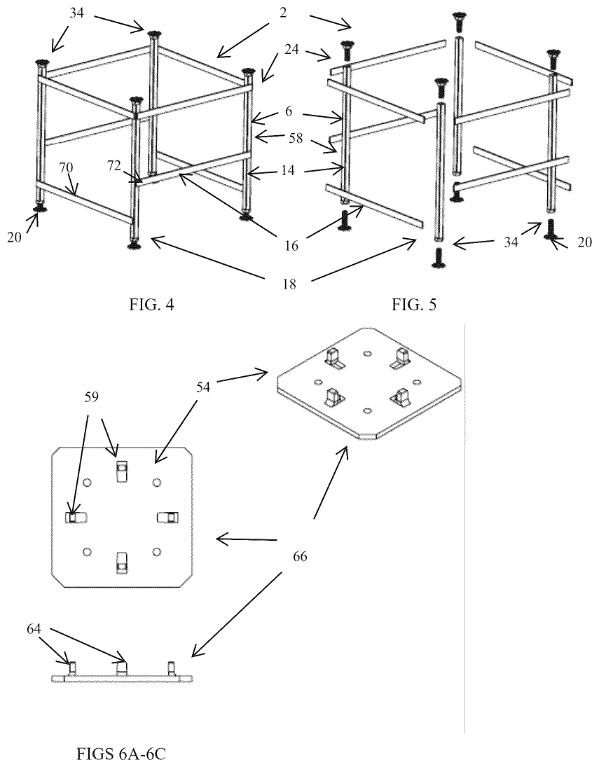

As shown for example in FIGS. 4, 5 and 15, in some embodiments the underfloor cubic support systems (UFCSS) 2 have cross-pieces that strengthen the cubic support structures and create multiple levels of support pathways under the RAF. Thus, such support crosspieces can be built into the floor support structure and facilitate routing of, e.g., wiring and plumbing lines in a well-organized fashion. In FIGS. 4 and 5, cross-support bars 16 of at least two different, adjacent UFCSS 3-D frames 58 are located at different heights 70, 72 within each of the two adjacent UFCSS 3-D frames 58, respectively. Same-height cross-support bars 16 can also provide desired, specified spaces to form an in-frame open area such as for carrying pipes or conduits. In addition, the complementary RAF panel unit 10 can comprise a flange or lip 74 extending beyond the sides 26 of the complementary RAF panel 8.

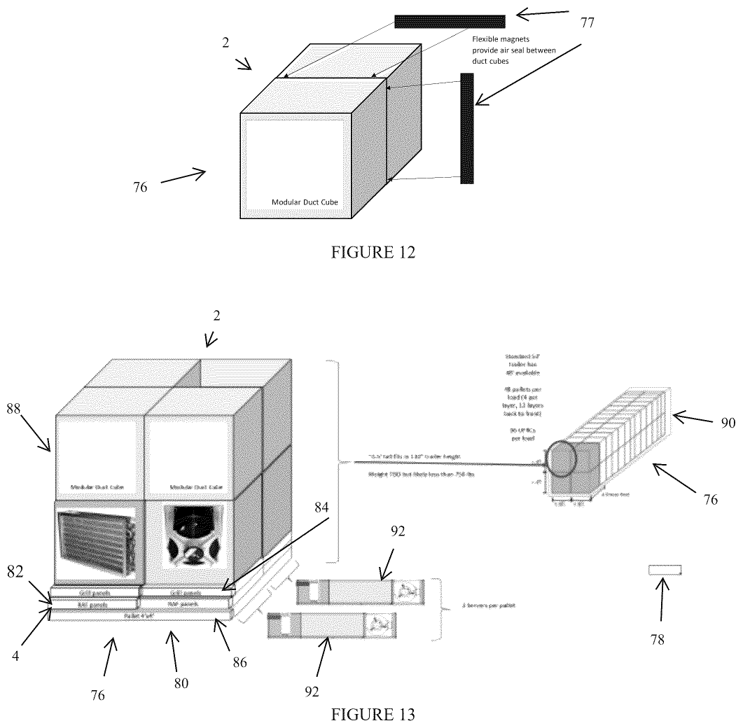

As shown in FIGS. 11B-13, the components can be packaged and delivered in underfloor cubic support system (UFCSS) kits 76. FIG. 11 shows exemplary modular cube mechanical and electrical components. FIG. 12 shows a duct cube example, and FIG. 13 shows a simplified shipping and installation example with 4′4′4+′pallet. The boxes in these figures are schematic representations of any suitable carrying or protect element, for example packaging boxes such as cardboard boxes or wooden boxes, or UFCSS 3-D frames, as well as combinations thereof such as UFCSS 3-D frames within cardboard or wooden boxes.

In certain embodiments, an underfloor cubic support system (UFCSS) kit 76 comprises a UFCSS 3-D frame 6, a complementary RAF panel and at least one of a) instructions 78 for use of the UFCSS kit 76 or b) packaging materials 80 for the UFCSS kit 76. The kit 76 can also comprise covering elements such as flexible magnets 77 that attach adjacent modular units to each other, protect seams between such modular units from dust or other contaminants, etc. The UFCSS kit 76 can comprise a plurality of UFCSS 3-D frames 6 and a corresponding plurality of complementary RAF panels 8. In the kit 76, the UFCSS 3-D frames 6, the complementary RAF panels 8, and other components such as grilles 84 as desired, can be stacked upon each other, for example where the UFCSS 3-D frames 6 are disposed above at least one stack 82 of the complementary RAF panels 8. The grilles 84 can be, for example for at least one input port and at least one output port in the RAF (see FIGS. 15 and 16).

The kit 86 components can be stacked on a pallet 86 in a 4×4×4 arrangement 88. The kit 76 can further comprise additional packaging or delivery components, such as a semi-tractor trailer or cargo container 90 or other large volume transport mode, or a truck or ship, containing the UFCSS 3-D frame and complementary RAF panel 8.

In FIGS. 15 and 16 (air flow reversed compared to FIG. 15), the UFCSS can be implemented in a data center server room 1504 within a building 1505 and can further comprise at least one underfloor server rack cooling system (UFSRCS) 1502. UFSRCS 1502 in the Figures is held within consecutive UFCSS 3-D frames 6 1556, and under the raised access floor (RAF) 1508 and above a subfloor 1528. UFCSS 1502 comprises UFCSS 3-D frames 1556 connected to and supporting a RAF panel 1558 of the RAF 1508 to provide a 3-D frame-RAF panel unit 1584. In the embodiment shown, UFCSS 3-D frames 1556 hold and support the RAF panels 1158 above the subfloor 1528 and the UFCSS 3-D frames 1556 comprise 4 vertical corner posts 1562 connected to each other by cross-support bars 1564, with each corner post 1562 comprising a foot 1566 at a lower end 1568 configured to contact the subfloor 1528 and a pedestal head 1570 at an upper end 1572 attached to the RAF panel and a variable height adjustment element 1574 to raise and lower the pedestal head 1570 relative to the foot 1566, and the complementary RAF panel comprises 4 complementary sides and the UFCSS 3-D frame 1556 does not extend beyond any of the sides of the RAF panel.

In some embodiments, including kit and system embodiments, for example in FIGS. 15 and 16, the UFCSS 1502 contains a first UFCSS 3-D frame 1582 that holds the hot air intake port 1508 and a second UFCSS 3-D frame 1576 holds cold air output port 1506. The fan 1518 and the cooling coil 1520 can be held in such first and/or second UFCSS 3-D frame, or third UFCSS 3-D frame 1580 can hold the cooling coil 1520 and a fourth UFCSS 3-D frame 1582 holds the fan 1518. In some embodiments, a separate UFCSS 3-D frame, which can be a third UFCSS 3-D frame 1580 (typically if it does not hold the cooling coil 1520 or fan 1520), holds a duct connection 1519 connectable to other UFCSS 3-D frames to connect disparate components of the UFSCRS. The various UFCSS 3-D frames typically have an RAF panel 1558, and air duct grilles 1507, 1515 and other data center server room components atop the 3-D frames. As shown in Figure e16, the UFCSS 1554 can also hold other elements and structures, for example water pipes 1600 and electric wiring 1602, and can contain instructions 1604 or other imaging describing the items underneath/within the RAF panel or UFCSS 3-D frame.

In some embodiments the raised access floor (RAF) 1508 comprises a plurality of the UFCSS 3-D frame-complementary RAF panel units 1584 herein. Adjacent UFCSS 3-D frame-complementary RAF panel units 1584 in the RAF are complementary such that there are no significant spaces between adjacent UFCSS 3-D frame-complementary RAF panel units 1584. The systems herein can further comprise at least one underfloor server rack 1606 cooling system (UFSRCS) 1502 complementary to the UFCSS 3-D frame-RAF panel units 1584, the UFSRCS 1502 located within UFCSS 3-D frames and operably connected to a space above the RAF via an input port 1508 and an output port 1506 in the RAF. The RAF can further comprise at least one server rack 1606 on the RAF. The RAF under a server rack 1606 can be located between the input port 1508 and the output port 1506 with a hot air back side of the server rack 1606 adjacent the input port 1508 and a cool air side of the server rack 1606 adjacent the cold air output port 1506.

In some aspects, the systems, methods, etc., herein include buildings and computer server room comprising the UFCSS herein as well as components thereof.

In further aspects, the embodiments herein include methods of making, using, transporting, etc., the UFCSS herein as well as components thereof. Some such methods comprise placing a complementary raised access floor panel (complementary RAF panel 8) atop its complementary UFCSS 3-D frame 6 to form a UFCSS 3-D frame-complementary RAF panel unit 10. Methods can also comprise placing a plurality of complementary raised access floor panels atop a plurality of complementary UFCSS 3-D frames to form a raised access floor comprising the UFCSS 3-D frame-complementary RAF panel units. Methods can further comprise placing at least one server rack on the RAF, including placing the at least one server rack on the RAF between an input port and an output port of an underfloor server rack cooling system (UFSRCS). Methods can also comprise placing a hot air back side of the server rack adjacent the input port and a cool air side of the server rack adjacent the cold air output port.

Methods can also further comprise placing a plurality of UFCSS 3-D frames and a plurality of complementary raised access floor in a kit, including placing them on a pallet, and placing the kit within a semi-tractor trailer, cargo container or similar large-volume shipping mode, as well as delivering the kit from a first location to a second desired location. The UFCSS 3-D frames and complementary RAF panels can also be from the kit 76.

Returning to a general discussion of the systems, devices, methods, herein, in some aspects, the cubic support structures and related systems provide or comprise one or more of the following, in one or more embodiments:
1) The RAF support posts or structures combine with the cubic support structure, so each cubic structure supports a single RAF panel (the panel can be unitary or have multiple components). The RAF and cubic support structures, etc., herein separate the vertical load bearing support function of a traditional pedestal from the lateral load “overturning moment” function of a traditional pedestal. This makes them independent of each other with the post bearing the vertical load and the cubic structure bearing the lateral load. Furthermore, the height of the RAF support structure is variable for each RAF support structure, with adjustability typically at both the foot and head, allowing the RAF support structures to each/independently follow irregular floor slopes making it easier to ensure the raised floor is flat. In other words, in some embodiments, the RAF support structures can be individually varied to correlate to variances in the subfloor or other support floor (such as a concrete slab) independent of the cubic support structure, so the RAF is flat.
2) The cubic support structures allow installation of the access floor grid without requiring measurement and placement at each corner of the floor panels; the cubic support structures can be individually adjusted as desired or needed on the fly to assure flatness. This can, e.g., speed up and economize the installation of such floors.
3) The cubic support structures reduce or eliminate the need to glue access floor support posts to the floor.
4) The cubic support structures automatically align the vertical support posts of the cubic support structure with the corners (or other desired connection point) of the RAF panel. Thus, in some aspects the cubic support structures are selected for, and configured to correspond to, the mounting dimensions of the floor panel.
5) The cubic support structures can have cross-pieces that strengthen the cubic support structures and that create multiple levels of support pathways under the RAF. Thus, such support crosspieces are built into the floor support structure and facilitate routing of, e.g., wiring and plumbing lines in a well-organized fashion.
6) The cubic support structures provide modular units for easily providing and placing a variety of underfloor mechanical and electrical components under the floor in correct locations with correct specifications, and in a well-organized manner. The modular unit also functions as the support structure for the RAF and the underfloor equipment described above. Modular units can also be configured to function as air flow ducts, in some embodiments including magnetic connectors to inhibit or prevent air leakage. The modular units also provide simplified logistics delivering and installing the products to the data center.

Various aspects, features and embodiments are set forth within this application, including this Summary and Detailed Description and attached drawings. Unless expressly stated otherwise or clear from the context, all embodiments, aspects, features, etc., can be mixed and matched, combined and permuted in any desired manner, and drawings are not necessarily dimensionally accurate.

All terms used herein are used in accordance with their ordinary meanings unless the context or definition clearly indicates otherwise. Also unless expressly indicated otherwise, in the specification the use of “or” includes “and” and vice-versa. Non-limiting terms are not to be construed as limiting unless expressly stated, or the context clearly indicates, otherwise (for example, “including,” “having,” and “comprising” typically indicate “including without limitation”). Singular forms, including in the claims, such as “a,” “an,” and “the” include the plural reference unless expressly stated, or the context clearly indicates, otherwise.

Unless otherwise stated, adjectives herein such as “substantially” and “about” that modify a condition or relationship characteristic of a feature or features of an embodiment, indicate that the condition or characteristic is defined to within tolerances that are acceptable for operation of the embodiment for an application for which it is intended.

The scope of the present devices, systems and methods, etc., includes both means plus function and step plus function concepts. However, the claims are not to be interpreted as indicating a “means plus function” relationship unless the word “means” is specifically recited in a claim, and are to be interpreted as indicating a “means plus function” relationship where the word “means” is specifically recited in a claim. Similarly, the claims are not to be interpreted as indicating a “step plus function” relationship unless the word “step” is specifically recited in a claim, and are to be interpreted as indicating a “step plus function” relationship where the word “step” is specifically recited in a claim.

From the foregoing, it will be appreciated that, although specific embodiments have been discussed herein for purposes of illustration, various modifications may be made without deviating from the spirit and scope of the discussion herein. Accordingly, the systems and methods, etc., include such modifications as well as all permutations and combinations of the subject matter set forth herein and are not limited except as by the appended claims or other claim having adequate support in the discussion and figures herein.

1. An underfloor cubic support system (UFCSS) for a raised access floor (RAF) comprising a UFCSS 3-D frame for holding and supporting a complementary raised access floor panel (complementary RAF panel) to provide a UFCSS 3-D frame-complementary RAF panel unit, wherein:
the UFCSS 3-D frame is configured to hold and support the complementary RAF panel above a subfloor and the UFCSS 3-D frame comprises at least 3 vertical corner posts connected to each other by cross-support bars, with each vertical corner post comprising a foot at a lower end configured to contact the subfloor and a pedestal head at an upper end holding the complementary RAF panel, and
the complementary RAF panel comprises at least 3 sides and is complementary to the UFCSS 3-D frame such that a horizontal size of the UFCSS 3-D frame and a horizontal size of the complementary RAF panel have an integral ratio relationship.

2. The underfloor cubic support system (UFCSS) of claim 1 wherein the UFCSS 3-D frame comprises at least one variable height adjustment element operably connected to the foot and the pedestal head to at least one of increase or decrease a distance between the foot and the pedestal head.

3. The underfloor cubic support system (UFCSS) of claim 1 wherein the UFCSS 3-D frame comprises at least a first variable height adjustment element at the foot and a second variable height adjustment element at the pedestal head.

4. The underfloor cubic support system (UFCSS) of claim 1 wherein the UFCSS 3-D frame is connected by attachment elements to the complementary RAF panel to provide the 3D frame-complementary RAF panel unit.

5. The underfloor cubic support system (UFCSS) of claim 1 wherein the complementary RAF panel floats atop the UFCSS 3-D frame to provide the 3D frame-complementary RAF panel unit.

6. The underfloor cubic support system (UFCSS) of claim 1 wherein the UFCSS 3-D frame comprises stringers spanning between upper ends of the corner posts.

7. The underfloor cubic support system (UFCSS) of claim 7 wherein a location of the complementary RAF panel atop the UFCSS 3-D frame is at least partially established by positioners on the stringers.

8. (canceled)

9. The underfloor cubic support system (UFCSS) of claim 6 wherein the stringers span between pedestal heads at upper ends of the corner posts.

10. The underfloor cubic support system (UFCSS) of claim 1 wherein a number of the corner posts of the UFCSS 3-D frame is the same as a number of vertices of the complementary RAF panel and wherein each corner post is attached to and supports a corresponding vertex of the complementary RAF panel.

11. The underfloor cubic support system (UFCSS) of claim 1 wherein the UFCSS 3-D frame has 4 corner posts and is cuboid.

12. The underfloor cubic support system (UFCSS) of claim 1 wherein the UFCSS 3-D frame has 4 corner posts and is a cube.

13. The underfloor cubic support system (UFCSS) of claim 1 wherein the complementary RAF panel comprises 4 sides.

14. The underfloor cubic support system (UFCSS) of claim 6 wherein the integral ratio relationship is one complementary RAF panel to one UFCSS 3-D frame.

15. The underfloor cubic support system (UFCSS) of claim 14 wherein a horizontal size of the complementary RAF panel does not extend beyond any of the sides of the horizontal size of the UFCSS 3-D frame.

16. The underfloor cubic support system (UFCSS) of claim 6 wherein the integral ratio relationship is two complementary RAF panels to one UFCSS 3-D frame.

17. The underfloor cubic support system (UFCSS) of claim 6 wherein the integral ratio relationship is four complementary RAF panels to one UFCSS 3-D frame.

18. The underfloor cubic support system (UFCSS) of claim 6 wherein the integral ratio relationship is one complementary RAF panel to two UFCSS 3-D frames.

19. The underfloor cubic support system (UFCSS) claim 1 wherein the UFCSS 3-D frame further comprises an anti-rotation element that locks the pedestal head at a desired height and position.

20. The underfloor cubic support system (UFCSS) of claim 1 wherein the pedestal head does not extend beyond the sides of the complementary RAF panel.

21. The underfloor cubic support system (UFCSS) of claim 1 wherein the pedestal head extends beyond the sides of the complementary RAF panel, the pedestal head further comprising adjacent-pedestal head attachment elements for attaching to at least one adjacent corner post of at least one adjacent UFCSS 3-D frame.

22. (canceled)

23. The underfloor cubic support system (UFCSS) of claim 1 wherein the underfloor cubic support system comprises at least a first UFCSS 3-D frame-complementary RAF panel unit and a second UFCSS 3-D frame-complementary RAF panel unit and the system further comprises at least one locator element disposed between each of the first UFCSS 3-D frame-complementary RAF panel unit and the second UFCSS 3-D frame-complementary RAF panel unit to hold the respective first UFCSS 3-D frame-complementary RAF panel unit and the second UFCSS 3-D frame-complementary RAF panel unit at a selected position relative to each other.

24. The underfloor cubic support system (UFCSS) of claim 22 wherein the locator element is connected between a) a first corner post of the first UFCSS 3-D frame-complementary RAF panel unit and b) a second corner post of the second UFCSS 3-D frame-complementary RAF panel unit.

25. The underfloor cubic support system (UFCSS) of claim 24 wherein underfloor cubic support system comprises at least a third UFCSS 3-D frame-complementary RAF panel unit and a fourth UFCSS 3-D frame-complementary RAF panel unit and wherein locator elements are located between and positioning adjacent corners of all four of the UFCSS 3-D frame-complementary RAF panel units.

26. The underfloor cubic support system (UFCSS) of claim 25 wherein the locator element is disposed between and connected to adjacent corner posts of all four of the UFCSS 3-D frame-complementary RAF panel units.

27. The underfloor cubic support system (UFCSS) of claim 23 wherein the locator element tilts between adjacent corner posts.

28. (canceled)

29. The underfloor cubic support system (UFCSS) of claim 27 wherein the locator element is a locator plate and wherein the locator plate comprises adjustable bevels such that a lower surface of the locator plate is tilted between and relative to adjacent UFCSS 3-D frame-complementary RAF panel units and an upper surface of the locator plate is level between and relative to adjacent UFCSS 3-D frame-complementary RAF panel units.

30. (canceled)

31. The underfloor cubic support system (UFCSS) of claim 1 wherein the cross-support bars of at least two UFCSS 3-D frames form an in-frame open area for carrying pipes or conduits.

32. The underfloor cubic support system (UFCSS) of claim 1 wherein the at least one of the UFCSS 3-D frame or the complementary RAF panel unit comprises a flange or lip extending beyond the sides of the complementary RAF panel.

33. The underfloor cubic support system (UFCSS) of claim 1 wherein at least one of the UFCSS 3-D frame, the complementary RAF panel or the complementary RAF panel unit comprises information thereon describing components contained within the UFCSS 3-D frame or under the complementary RAF panel unit, respectively.

34. The underfloor cubic support system (UFCSS) of claim 33 wherein the information comprises printed words, maps or diagrams identifying underfloor components contained within the UFCSS 3-D frame or under the complementary RAF panel unit.

35. The underfloor cubic support system (UFCSS) of claim 33 wherein the information comprises printing identifying underfloor components contained within the UFCSS 3-D frame or under the complementary RAF panel unit and at least one adjacent UFCSS 3-D frame or complementary RAF panel unit, respectively.

36-92. (canceled)

93. The underfloor cubic support system (UFCSS) of claim 2 wherein the UFCSS 3-D frame comprises at least a first variable height adjustment element at the foot and a second variable height adjustment element at the pedestal head.
